(19) United States
(12) Patent Application Publication
(10) Pub. No.: US 2004/0248420 A1
(43) Pub. Date: Dec. 9, 2004

(54) Substrate with microstructure formed thereon and manufacturing method thereof

(76) Inventors: Sun Jin Yun, Taejon (KR); Jungwook Lim, Taejon (KR); Jin Ho Lee, Taejon (KR)

Correspondence Address: JACOBSON, PRICE, HOLMAN & STERN, PROFESSIONAL LIMITED LIABILITY COMPANY, 400 Seventh Street. N.W., Washington, DC, 20004, US

(21) Appl. No.: 10/777,102

(22) Filed: Feb. 13, 2004

(30) Foreign Application Priority Data
Jun. 9, 2003 (KR) 2003-36796

(51) Int. Cl. H01L 21/302; H01L 21/461

(52) U.S. Cl. 438/706

(57) ABSTRACT

Disclosed are a substrate with a microstructure formed thereon and a manufacturing method thereof, in which one substrate is attached to the other substrate with a micropattern formed thereon to form air gaps between the substrates, thereby relaxing stress applied to the substrates at a process of manufacturing a semiconductor device or display panel and also easily detaching the other substrate (temporary substrate) from one substrate (upper substrate) after the completion of the process. The substrate includes a temporary substrate supporting an upper substrate on which a device is formed at a process of manufacturing the device, and removed from the upper substrate after the process, a buffer layer formed on an upper surface of the temporary substrate to have a plurality of shapes with air gaps spaced apart from each other at regular intervals, and an adhesive layer formed on the buffer layer so that the upper substrate is adhered to an upper surface of the adhesive layer. Since the air gaps relax the stress applied to the substrate at the process of manufacturing the microelectronic device, display panels, or sensor devices, it can minimize deformation of the substrate, thereby reducing a fraction defective.

### BACKGROUND OF THE INVENTION

1. Field of the Invention

The present invention relates to a substrate, and more particularly, to a substrate with a microstructure formed thereon and a manufacturing method thereof, in which one substrate is attached to the other substrate with a micropattern formed thereon to form air gaps between the substrates, thereby relaxing stress applied to the substrates during a process of manufacturing devices, such as a semiconductor device or display panel, and also easily detaching the other substrate (temporary substrate) from one substrate (upper substrate) after the completion of the process.

2. Background of the Related Art

Recently, in order to obtain light and thin devices, especially for information display appliances or microelectronics, a device is fabricated on a plastic substrate, or a metal foil substrate is utilized. There are also some other advantages because the substrates are flexible or foldable.

For example, the plastic substrate is employed as the substrates of an organic thin film transistor or an organic electroluminescence display which is in the spotlight of next-generation display, such as a mobile communication terminal, a personal digital assistant, a camcorder, a hand-held PC, a video phone or the like.

Although a very thin silicon or glass is not flexible as much as a plastic substrate or a metal foil, it has an advantage of significantly reducing the weight of product. Therefore, it has widely used at the manufacture of the semiconductor device.

In the case of manufacturing a device on the plastic substrate, since the plastic substrate itself is very flexible, and suffers from thermal expansion and retraction due to the large thermal expansion coefficient, a position of align key in photolithography is continuously varied at the process of manufacturing the device. Further, the entire substrate is deformed in progress of the process, thereby significantly deteriorating characteristics of the device. The flexible metal foil substrate also has drawbacks similar to those of the plastic substrate.

In order to overcome the above drawbacks, the plastic substrate or metal foil substrate (upper substrate) is adhered to a temporary substrate (lower substrate) made of a solid material, such as glass, silicon or metal, and having low flexibility and low thermal expansion coefficient by use of an adhesive or adhesive tape. After carrying out the process of manufacturing the microelectronic or the display devices on the upper substrate, the upper substrate is detached from the lower supporting substrate.

FIGS. 1a and 1b are cross-sectional views of a conventional substrate with the upper substrate adhered to the temporary substrate, so as to overcome the drawbacks of the plastic substrate or the metal foil substrate. Referring to FIG. 1a, an adhesive layer 2 is formed on a temporary substrate 1, and an upper substrate 3 such as plastic substrate is adhered to the temporary substrate by the adhesive layer. Referring to FIG. 1b, after the temporary substrate 1 is formed with a buffer layer 4 composed of SiO₂, Al₂O₃, an organic film, an oxide film, or a nitride film, the adhesive layer 2 is formed on the buffer layer 4, so that the plastic substrate 3 is adhered to the temporary substrate. The buffer layer is of a middle value between coefficients of thermal expansion of two substrates to relax the thermal stress. The buffer layer should be also easily etched in order to easily detach the temporary substrate after the process.

However, it cannot effectively relax the stress generated between two substrates having different thermal expansion coefficient and between an inorganic thin film formed on the plastic substrate 3 and the plastic substrate, during carrying out the following processes after adhering the upper substrate 3 and temporary substrate 1. Therefore, it may negatively affect a lifetime and performance of a device fabricated on the upper substrate.

Meanwhile, the inorganic material used in the temporary substrate 1, such as silicon or silicon oxide, has a coefficient of thermal expansion of a few ppm/° C., while the plastic substrate used as the upper substrate 3 has a thermal expansion coefficient of several tens ppm/° C. Therefore, there is a large difference in coefficients of thermal expansion of both substrates.

In addition, after the process of fabricating the device is completed, it is difficult to detach the temporary substrate from the upper substrate because the adhesive layer is formed on the entire surfaces of the upper and temporary substrates.

### SUMMARY OF THE INVENTION

Accordingly, the present invention is directed to a substrate with a microstructure formed thereon that substantially obviates one or more problems due to limitations and disadvantages of the related art.

An object of the present invention is to provide a substrate with a microstructure formed thereon, in which an air gap is formed between two substrates having different characteristics due to a kind of material, a thickness and the like when adhering two substrates to form a substrate, so as to relax stress applied to the substrates during a process of manufacturing a semiconductor device or display panel.

To achieve the object and other advantages, according to one aspect of the present invention, there is provided a substrate with a microstructure formed thereon, the substrate comprising: a temporary substrate supporting an upper substrate on which a device is formed at a process of fabricating the device, and removed from the upper substrate after the process; a buffer layer formed on an upper surface of the temporary substrate to have a plurality of shape with air gaps spaced apart from each other at regular intervals; and an adhesive layer formed on the buffer layer so that the upper substrate is adhered to an upper surface of the adhesive layer.

According to other aspect of the present invention, there is provided a method for manufacturing a substrate with a microstructure formed thereon, the method comprising the steps of: a) forming a buffer layer having air gaps spaced apart from each other at regular intervals and a plurality of shape on an upper surface of a temporary substrate or a lower surface of an upper substrate; b) forming an adhesive layer on the surface of the buffer layer; and c) adhering the temporary substrate to the upper substrate using the adhesive layer formed on the surface of the buffer layer.

According to another aspect of the present invention, there is provided a method for manufacturing a substrate with a microstructure formed thereon, the method comprising the steps of: a) patterning by photolithography and etching one surface of a temporary substrate to form air gaps spaced apart from each other at regular intervals on the temporary substrate supporting an upper substrate on which a semiconductor device is formed; b) forming an adhesive layer on the surface of the buffer layer with the air gaps formed thereon; c) adhering the temporary substrate to the upper substrate using the adhesive layer; d) processing the device fabrication on the upper substrate with the temporary substrate underneath supporting the upper substrate; and e) removing the temporary substrate to separate the upper substrate after the completion of the device processing on the upper substrate.

According to the present invention, the substrate is formed by adhering the upper substrate to the temporary substrate having a physical property different from that of the upper substrate, with the buffer layer containing air gaps formed on the temporary substrate, in which it is difficult for the upper substrate itself to be used in the process of manufacturing a microelectronic device, display panel or sensor device since the upper substrate is very flexible or has a high thermal expansion coefficient. Therefore, the air gaps can effectively reduce the stress applied to the upper substrate at the process, and thus the deformation of the upper substrate may be prevented. In addition, it can minimize the thermal imbalance between a surface of the upper substrate and an interior thereof at the process.

Further, when the temporary substrate is removed from the upper substrate after the completion of the process, it can easily detach the temporary substrate since the adhered area is small due to the air gaps.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIGS. 1a and 1b are cross-sectional views of a conventional substrate with an upper substrate adhered to a temporary substrate;

FIG. 2 is a cross-sectional view of a substrate with a microstructure formed thereon;

FIG. 3 is a flowchart showing a process of manufacturing a substrate with a microstructure formed thereon according to a first preferred embodiment of the present invention;

FIG. 4 is a flowchart showing a process of manufacturing a substrate with a microstructure formed thereon according to a second preferred embodiment of the present invention;

FIG. 5 is a flowchart showing a process of manufacturing a substrate with a microstructure formed thereon according to a third preferred embodiment of the present invention;

FIG. 6 is a flowchart showing a process of manufacturing a substrate with a microstructure formed thereon according to a fourth preferred embodiment of the present invention; and

FIGS. 7a to 7f are perspective views showing various embodiments of a substrate with a microstructure formed thereon according to the present invention.

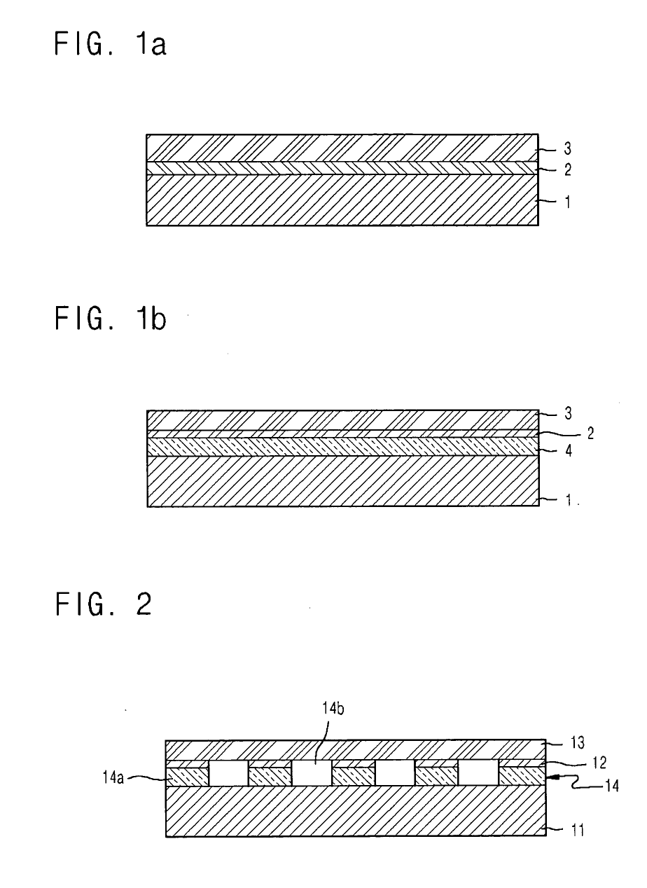

### DETAILED DESCRIPTION OF THE PREFERRED EMBODIMENTS

A preferred embodiment according to the present invention will now be explained with reference to the accompanying drawings.

FIG. 2 is a cross-sectional view of a substrate with a microstructure formed thereon according to one preferred embodiment of the present invention.

The present invention includes, as shown in FIG. 2, a lower/temporary substrate 11, an upper substrate 13 supported by the temporary substrate 11, and a buffer layer 14 formed as an upper layer of the temporary substrate 11. A device is formed on an upper surface of the upper substrate 13 at a process of manufacturing the device, and the temporary substrate 11 is detached from the upper substrate 13 after the process.

The buffer layer 14 formed on the upper surface of the temporary substrate is patterned and formed by an etching process to have a plurality of shape 14a with air gaps 14b spaced apart from each other at regular intervals.

An adhesive layer 12 is formed on the buffer layer 14 formed by the etching process, so that the upper substrate 13 is seated on adhered to an upper surface of the adhesive layer 12 to complete the substrate.

It manufactures the substrate with the microstructure formed thereon according to the present invention through the following process.

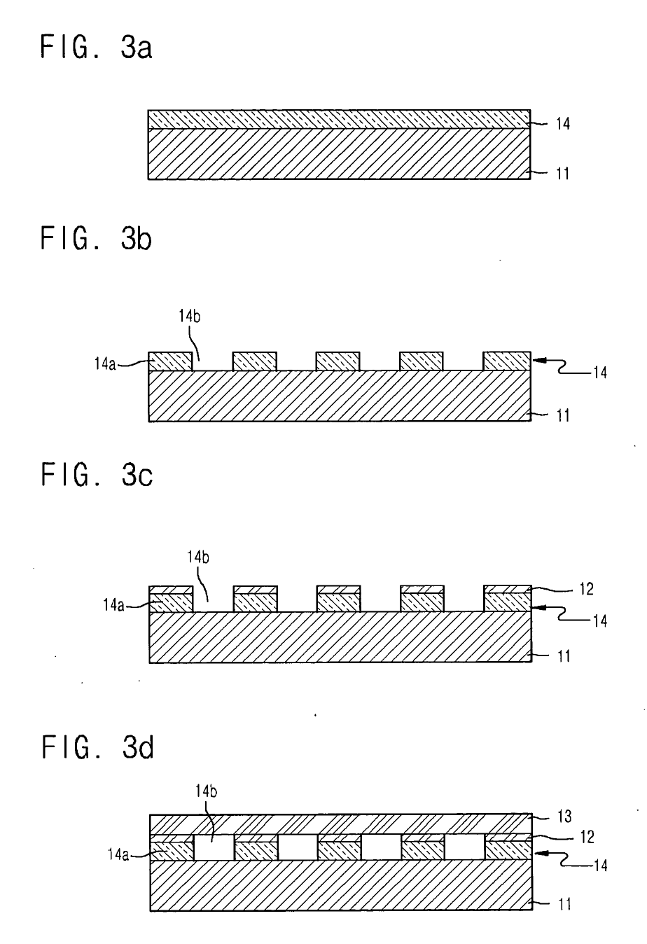

FIG. 3 is a flowchart showing a process of manufacturing the microstructure formed thereon according to a first preferred embodiment of the present invention.

Referring to FIG. 3, the temporary substrate 11 is a substrate to support a substrate on which a device is integrated, and is temporarily adhered to the upper substrate at a fabrication process of a semiconductor device, a display panel, or a sensor device.

Since the upper substrate (flexible substrates such as plastic or metal foil substrate) 13 has high flexibility and a high coefficient of thermal expansion, it is difficult for the upper substrate 13 to carry out the process of manufacturing on the flexible substrate. In order to overcome the drawback of the upper substrate 13, the temporary substrate 11 may be made of any one of Si, SiO₂, Al₂O₃, copper, copper alloy, aluminum, aluminum alloy, and glass, or may be made of a mixture of at least two elements described above. Alternatively, the temporary substrate may be made in a multiplayer structure by forming separate layers each made of the respective elements.

Meanwhile, the temporary substrate 11 may be made of the same plastic material as that of the upper substrate 13. In this case, the temporary substrate 11 is thicker than a thickness of the upper substrate so that the temporary substrate has a function of supporting the upper substrate 13.

Referring to FIG. 3a, the buffer layer 14 is formed on the upper surface of the temporary substrate 11 made of the above material under the condition. The buffer layer 14 is made of any one of an oxide film, such as SiO₂ and Al₂O₃, an oxynitride film, such as AlON and SiON, a nitride film, such as Si₃N₄ and AlN, organic film such as photoresist, and SOG (spin-on-glass), or is made of a mixture of at least two elements described above. Alternatively, the buffer layer may be made in a multiplayer structure by forming separate layers each made of the respective elements.

Further, the buffer layer 14 may be made of an alloy containing a metal (Al, Cu), copper or aluminum, an organic material or a photosensitive material. In the case that the buffer layer 14 is formed with the organic photosensitive material, there are some advantages that the patterning is easily carried out, one step of etching the pattern is reduced in relation to a case of using other thin film material, and the thin film is easily removed.

Then, in order to form the air gap 14b having a regular interval on the temporary substrate 11 on which the buffer layer 14 is formed, after a pattern is formed on the buffer layer 14 using a photo mask, a micropattern 14a is formed by performing an etching process (see FIG. 3b).

Accordingly, the buffer layer 14 consists of the plurality of shape 14a formed on the upper surface of the lower substrate 11 and the air gaps 14b formed between the shapes.

At that time, the buffer layer 14 may be patterned in many rows or in shape of hexahedron or cylindrical islands by differently forming the mask pattern.

In the case of etching the buffer layer 14 by forming the pattern as the hexahedron or cylindrical islands, since a stress relaxed region of the air gap 14b is enlarged, it may reduce the stress applied to the substrate at the process of manufacturing the microelectronic device or the display panel and deterioration of the substrate and device.

Alternatively, the buffer layer may be easily formed by manufacturing it as a paste type without photolithography and by performing screen printing, inkjet printing or spraying technique using a shadow mask. In the case of forming the buffer layer having a pattern of a given thickness by using the process of forming a thick film, such as screen printing, inkjet printing or spraying technique, the air gap is formed when the printing is performed, so that it is more suitable to manufacture a substrate of a large area and it can reduce a manufacturing cost.

And then, the air gaps 14b are formed between the buffer layers 14 to form a plurality of shapes 14a, and the adhesive layer 12 is formed on the upper surfaces 14a of the shape layers 14a.

The adhesive layer 12 is to adhere the temporary substrate 11 with the upper substrate 13, and generally utilizes a double sided tape, a liquid adhesive or organic film capable of withstanding a temperature of more than 100° C. at performing a thermal process of devices.

Referring to FIG. 3c, the upper surface of the plurality of shapes 14a formed on the buffer layer 14 at regular intervals are applied with a liquid adhesive to form the adhesive layer 12.

When the adhesive is formed on the shapes 14a of the buffer layer 14, the upper substrate 13 is adhered to the adhesive layer 12 so that the upper substrate 13 is adhered to the temporary substrate 11 to complete the manufacture of the substrate with the microstructure (shape layer) 14a formed thereon (see FIG. 3d).

The upper substrate 13 is made of any one of plastic, stainless steel, copper, copper alloy, aluminum, aluminum alloy, silicon, and glass, and is adhered to the temporary substrate 11.

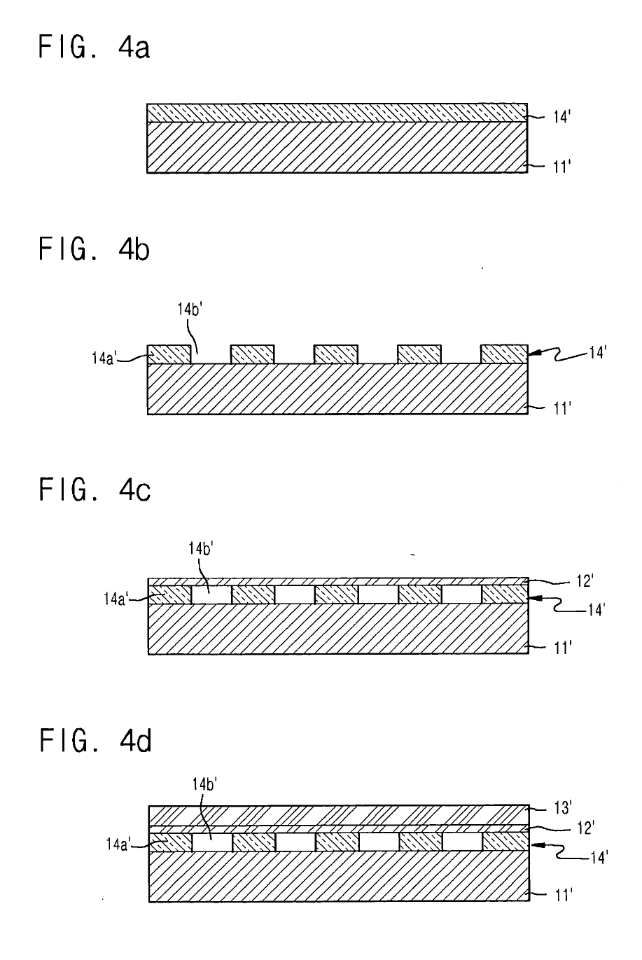

FIG. 4 is a flowchart showing a process of manufacturing the substrate with a microstructure formed thereon according to a second preferred embodiment of the present invention.

Comparing with FIG. 3, the processes of manufacturing the substrate and the conditions shown in FIGS. 3a, 3b and 3d are substantially identical to those shown in FIGS. 4a′, 4b′ and 4d′, except for the process of forming the adhesive layer 12 on the upper surface of the buffer layer 14. Accordingly, only the process of forming an adhesive layer 12′ shown in FIG. 4c′ will now be described.

If a buffer layer 14 is formed with a plurality of shapes 14a′ and air gaps 14b′ formed between the shapes at regular intervals (see FIG. 4b), a double sided tape is laid on a floor from which the double sided tape is easily detached, and an upper surface of the buffer layer 14′ is attached to the double sided tape laid on the floor by turning over a temporary substrate 11′ with the buffer layer 14′ formed thereon, thereby forming the adhesive layer 12′ on the upper surface of the buffer layer 14′ consisting of the plurality of shapes 14a′ (see FIG. 4c′). An upper substrate 13′ is adhered to the upper surface 12′ formed by the double sided tape (see FIG. 4d′).

Alternatively, the double sided tape is attached to a lower surface of the upper substrate 13′, and the adhesive layer 12′ of the upper substrate 13′ is adhered to the upper surface of the buffer layer 14′ of the temporary substrate 11′, thereby completing the manufacture of the substrate.

With the process of manufacturing the substrate according to the present invention, the buffer layer is not formed on the upper surface of the temporary substrate, and one side of the temporary substrate to be adhered to the upper substrate is patterned or etched to form the air gap arranged in many rows or in shape of islands, or the substrate is processed by a laser etching to form the air gap.

According to the formation of such an air gap, the plurality of shapes on the buffer layer are spaced apart form each other at regular intervals, thereby minimizing an area abutting against the adhesive layer. Therefore, there is an advantage that after the device is manufactured on the upper substrate, the temporary substrate is easily detached from the upper substrate. In particular, in the case the temporary substrate is detached by etching the buffer layer, an etching solution is easily permeated through the air gap, and a volume to be etched is small, thereby significantly reducing processing time and efforts.

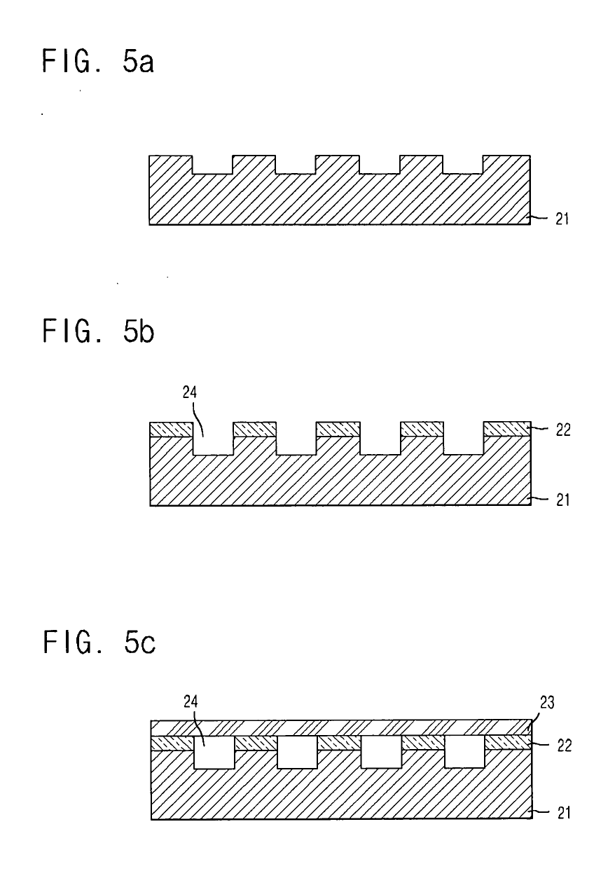

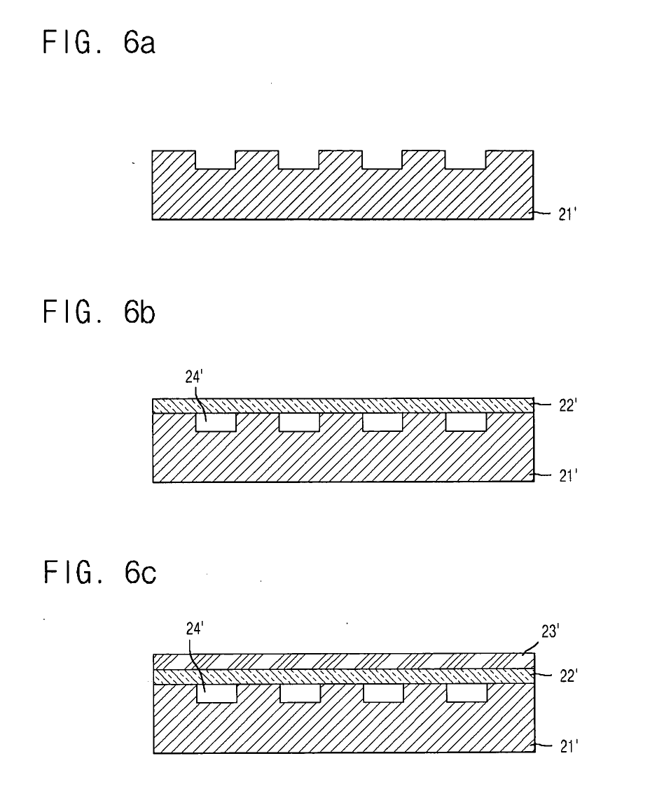

FIGS. 5 and 6 are flowcharts showing a process of manufacturing a substrate with a microstructure formed thereon according to third and fourth embodiments of the present invention, in which an air gap is directly formed on one side of a temporary substrate, without forming buffer layers.

As shown in FIG. 5, according to the process of manufacturing the substrate without forming the buffer layers, after one side of the temporary substrate 21 is patterned and etched, an adhesive layer 22 is formed on the etched side of the temporary substrate using a liquid adhesive, and an upper substrate 23 is adhered to the adhesive layer 22.

As shown in FIG. 6, after one side of a temporary substrate 21′ is patterned and etched, as the process of FIG. 5, an adhesive layer 22′ is formed on the etched side of the temporary substrate using a double sided tape, and an upper substrate 23′ is adhered to an upper surface of the adhesive layer 22′.

In the above embodiments, although the process of forming the adhesive layer using the liquid adhesive or double sided tape are described, the present invention may adhere the temporary substrate and the upper substrate, in the state of not forming a physical adhesive layer.

For example, the buffer layer formed on the temporary substrate may be secured to the upper substrate using electrostatic force. In this case, two substrates must be made of a dielectric material, such as plastic.

The adhesive may be adapted to be removed by wet etching, mechanical releasing or ultraviolet radiation, after completing the process.

In the above embodiments, if the upper substrate is selected as the plastic substrate, it is heat treated at a temperature of about 200° C. during a long time before attaching the temporary substrate, in order to minimize deformation of the plastic substrate due to the heat process. Alternatively, the upper surface of the substrate may be coated with an organic/inorganic thin film to prevent the permeation of water vapor.

The buffer layer or adhesive layer may be formed on a lower surface of the upper substrate, instead of the upper surface of the temporary substrate, if necessary. Specifically, the process of manufacturing the temporary substrate is identically applied to the upper substrate, and the temporary substrate is adhered to the upper substrate to complete the manufacture of the substrate.

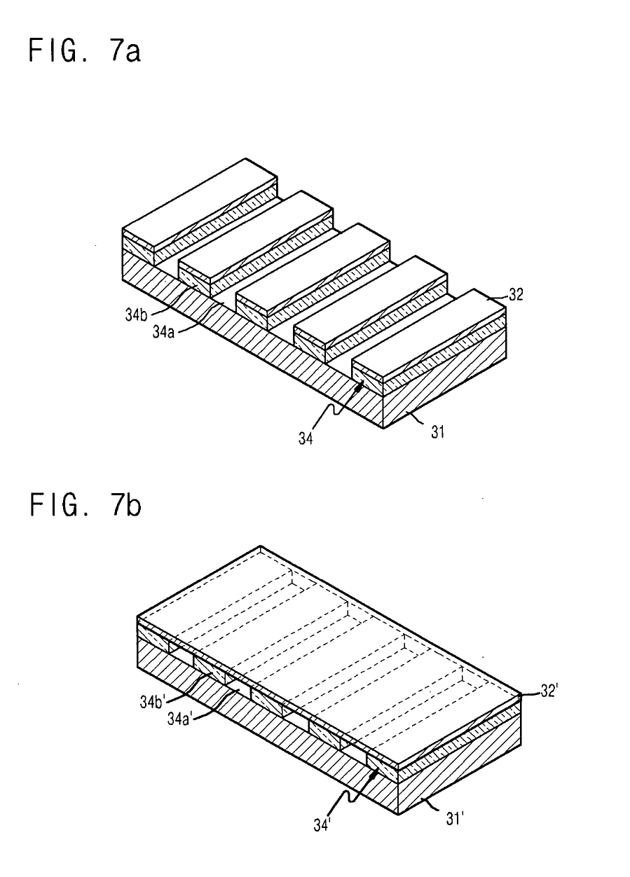

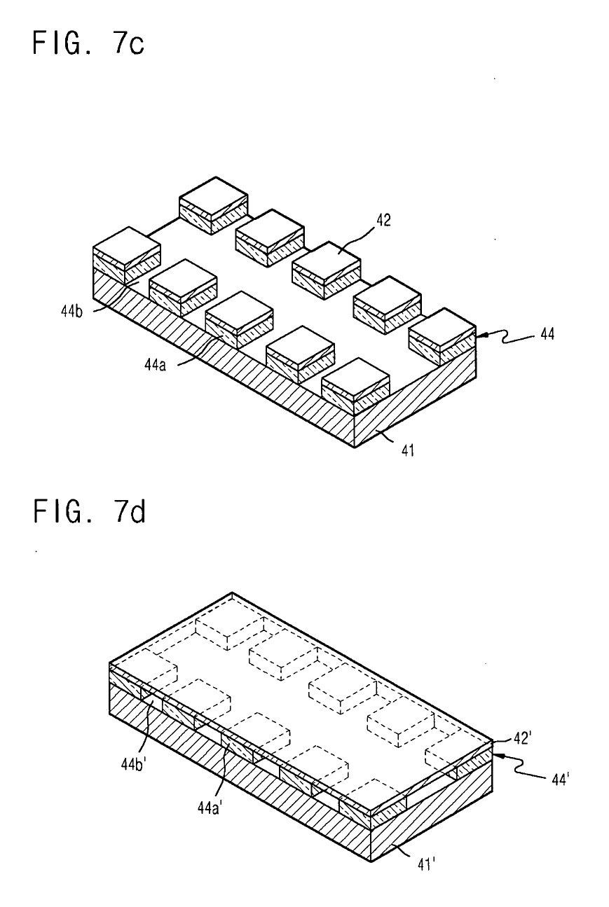

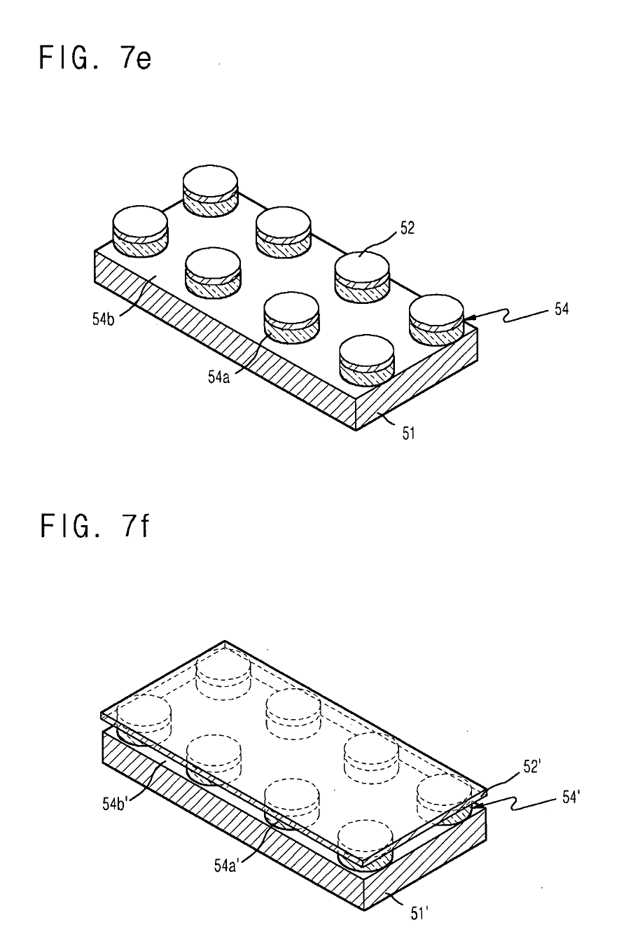

FIGS. 7a to 7f are perspective views showing various embodiment of a substrate with a microstructure formed thereon.

Referring to FIGS. 7a and 7b, after temporary substrates 31 and 31′ are patterned and etched to form a microstructure, i.e., buffer layers 34 and 34′, arranged in many rows, an adhesive layer is formed by a liquid adhesive 32 and a double sided tape 32′, respectively. Referring to FIGS. 7c and 7d, after temporary substrates 41 and 41′ are patterned and etched to form buffer layers 44a and 44a′ arranged in shape of isolated hexahedral islands, an adhesive layer is formed by a liquid adhesive 42 and a double sided tape 42′, respectively. Referring to FIGS. 7e and 7f, after temporary substrates 51 and 51′ are patterned and etched to form buffer layers 54a and 54a′ arranged in shape of isolated cylindrical islands, an adhesive layer is formed by a liquid adhesive 52 and a double sided tape 52′, respectively. At that time, the adhesive layer made of the double sided tapes 32′, 42′ and 52c′ may be formed on the lower surface of the upper substrate.

As described above, any one of upper and lower substrates is formed with a buffer layer, and the buffer layer is patterned and etched to a plurality of shapes spaced apart from each other at regular intervals and simultaneously to form air gaps 15. Therefore, the present invention relaxes the stress applied to the substrate at the process of manufacturing devices and minimizes thermal unbalance of the device during the process. Further, the present invention may prevent misalign of the process due to the deformation of the upper substrate.

The forgoing embodiments are merely exemplary and are not to be construed as limiting the present invention. The present teachings can be readily applied to other types of apparatus. The description of the present invention is intended to be illustrative, and not to limit the scope of the claims. Many alternatives, modifications, and variations will be apparent to those skilled in the art.

What is claimed is:

1. A substrate with a microstructure formed thereon, the substrate comprising:
a temporary substrate supporting an upper substrate on which a device is formed at a process of manufacturing the device, and removed from the upper substrate after the process;
a buffer layer formed on an upper surface of the temporary substrate to have a plurality of shapes with air gaps spaced apart from each other at regular intervals; and
an adhesive layer formed on the buffer layer so that the upper substrate is adhered to an upper surface of the adhesive layer.

2. The substrate as claimed in claim 1, wherein the temporary substrate is made of at least one of Si, SiO₂, Al₂O₃, copper, copper alloy, aluminum, aluminum alloy, and glass.

3. The substrate as claimed in claim 1, wherein the buffer layer is made of at least one of SiO₂, Al₂O₃, AlON, SiON, Si₃N₄, AIN, SOG (spin-on-glass), photosensitive material, Cu, Cu alloy, Al, and Al alloy.

4. The substrate as claimed in claim 1, wherein the buffer layer is patterned and etched to form a plurality of shapes arranged in many rows or to form a plurality of shapes arranged in hexahedron or cylindrical islands, with air gaps being spaced apart from each other at regular intervals.

5. The substrate as claimed in claim 1, wherein the adhesive layer is made of any one of a double sided tape, a liquid adhesive, and organic film, to withstand a hot process of more than 100° C.

6. The substrate as claimed in claim 1, wherein the upper substrate is made of any one of plastic, stainless steel, copper, copper alloy, aluminum, aluminum alloy, silicon, and glass.

7. A method for manufacturing a substrate with a microstructure formed thereon, the method comprising the steps of:
a) forming a buffer layer having air gaps spaced apart from each other at regular intervals and a plurality of shapes on an upper surface of a temporary substrate or a lower surface of an upper substrate;
b) forming an adhesive layer on an upper surface of the buffer layer; and
c) adhering the temporary substrate to the upper substrate using the adhesive layer formed on the upper surface of the buffer layer.

8. The method as claimed in claim 7, wherein in the step a, after the flat buffer layer of a given thickness formed on the upper surface of the temporary substrate or the lower surface of the upper substrate is patterned by photolithography, the patterned buffer layer is etched to form the air gaps spaced apart from each other at regular intervals and the plurality of shapes.

9. The method as claimed in claim 7, wherein in the step a, the air gaps spaced apart from each other at regular intervals and the plurality of shape layers are formed on the upper surface of the temporary substrate or the lower surface of the upper substrate using a screen printing method or an inkjet printing method.

10. The method as claimed in claim 7, wherein in the step a, the buffer layer is made of at least one of SiO₂, Al₂O₃, AlON, SiON, Si₃N₄, AlN, SOG (spin-on-glass), photosensitive material, Cu, Cu alloy, Al, and Al alloy.

11. The method as claimed in claim 7, wherein in the step b, the adhesive layer is made of any one of a double sided tape, a liquid adhesive, and organic film, to withstand a hot process of more than 100° C.

12. A method for manufacturing a substrate with a microstructure formed thereon, the method comprising the steps of:
a) patterning and etching one surface of a temporary substrate to form air gaps spaced apart from each other at regular intervals, the temporary substrate supporting an upper substrate, on which a semiconductor device is formed, at a process of manufacturing the semiconductor device, and removed from the upper substrate after the process is completed;
b) forming an adhesive layer on the upper surface of the temporary substrate with the air gaps formed thereon; and
c) adhering the temporary substrate to the upper substrate using the adhesive layer.
